(19) United States
(12) Patent Application Publication
(10) Pub. No.: US 2010/0289107 A1
(43) Pub. Date: Nov. 18, 2010

(54) PHOTODIODE WITH INTERFACIAL CHARGE CONTROL BY IMPLANTATION AND ASSOCIATED PROCESS

(75) Inventors: Jorge Regolini, Bernin (FR); Luc Pinzelli, Grenoble (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignees: STMICROELECTRONICS S.A., Montrouge (FR); STMICROELECTRONICS (CROLLES 2) SAS, Crolles Cedex (FR)

(21) Appl. No.: 12/780,488

(22) Filed: May 14, 2010

(30) Foreign Application Priority Data
May 18, 2009 (FR) 0953289

(51) Int. Cl. H01L 31/10; H01L 31/18

(52) U.S. Cl. 257/463; 438/87; 257/E31.053

(57) ABSTRACT

A photodiode includes a first doped layer and a second doped layer adjacent to the first doped layer and sharing a common face. A deep isolation trench is provided adjacent the photodiode having a face contiguous with the first doped layer and the second doped layer. A free face of the second doped layer is in contact with a conducting layer. A protective layer capable of generating a layer of negative charge is provided at the interface between, on one side, the first doped layer and the second doped layer and, on the other side, the deep isolation trench.

### PRIORITY CLAIM

The present application claims priority from French Application for Patent No. 09 53289 filed May 18, 2009, the disclosure of which is hereby incorporated by reference.

### TECHNICAL FIELD

The invention relates to the field of photodiodes and more particularly to photodiodes produced in matrices.

### BACKGROUND

Photodiode technology relies on two key parameters.

The first parameter is the sensitivity of the photodiode, which represents the capacity of the photodiode to collect photogenerated charge carriers. This parameter controls the intensity of the current generated for a given illumination.

The second parameter is the dark current, which represents the current flowing through the photodiode when no light illuminates the photodiode. This parameter controls the difference in intensity of the current generated for a given difference in illumination.

A relatively large portion of the electrons generated in the photodiode do not contribute to the photocurrent as they are trapped by structural defects or recombination zones. Likewise, in the case of photodiode matrix sensors, the reduction in size creates influencing effects between adjacent photodiodes, degrading the performance of all the diodes.

In this regard, the reader may refer to the document “Deep Trench isolation for crosstalk suppression in active pixel sensors with 1.7 nm pixel pitch”, by B. J. Park et al., Japanese Journal of Applied Physics, Vol. 46, No. 4B, 2454-2457 (2007), the disclosure of which is incorporated by reference, which describes the production of deep isolation trenches and their use in matrix photosensors so as to limit neighboring effects.

However, deep isolation trenches may play a similar role to structural defects or recombination centers. It will be recalled that recombination centers destroy charge carriers by combining them with carriers of opposite charge, for example by combining holes with electrons.

This is because deep isolation trenches generally comprise an insulating material and are produced in a semiconductor medium. Moreover, an inherent property to silicon/oxide or silicon/nitride interfaces is to have a positive surface charge capable of attracting the photogenerated electrons. It will therefore be understood that deep isolation trenches act as traps for the photogenerated electrons.

It is therefore desirable to minimize or eliminate the trapping of photogenerated electrons in the vicinity of the deep isolation walls.

There is also a need for a device of the photodiode type in which the trapping of the photogenerated electrons in the vicinity of the deep isolation walls is minimized or eliminated.

### SUMMARY

In an embodiment, a photodiode comprises a first doped layer and a second doped layer that have a common face, at least one deep isolation trench having a face contiguous with the first doped layer and the second doped layer, and wherein a free face of the second doped layer is in contact with a conducting layer.

This photodiode furthermore includes a protective layer capable of generating a layer of negative charge at the interface between, on one side, the first doped layer and the second doped layer and, on the other side, the deep isolation trench.

The protective layer may be produced by implantation of p-type doping species.

The protective layer may be produced by implantation of species chosen from boron and indium.

The protective layer may also include implanted carbon.

According to another aspect, a process is presented for producing at least one deep isolation trench, each deep isolation trench being produced between two photodiodes made from a structure comprising a first doped layer and a second doped layer that have a common face, a free face of the second doped layer being in contact with a conducting layer. The process includes a step during which: a protective layer is formed by implanting a species at the interface between, on one side, a first doped layer and a second doped layer and, on the other side, the deep isolation trench, the implanted species having the property of creating a layer of negative charge in contact with the doped silicon.

The implanted species may be a p-type doping species.

The implanted species may be chosen from boron and indium.

Carbon may also be implanted at the interface during formation of the protective layer.

At least two different species chosen from the implanted species may be co-implanted.

### BRIEF DESCRIPTION OF THE DRAWINGS

Other objects, features and advantages will become apparent on reading the following description given solely by way of non-limiting example and with reference to the appended drawings in which:

FIG. 1 illustrates the main elements of a photodiode according to the prior art;

FIG. 2 illustrates the main elements of a photodiode with a protective layer; and

FIG. 3 illustrates the implantation process associated with the production of a photodiode with a protective layer.

### DETAILED DESCRIPTION OF THE DRAWINGS

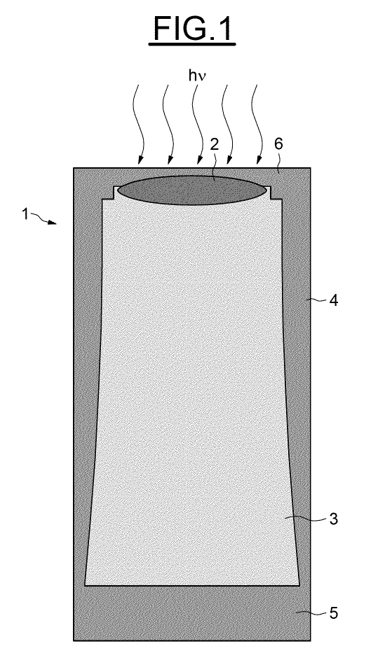

FIG. 1 shows a photodiode according to the prior art. The photodiode 1 has an opening on a two-layer stack comprising two layers of opposed doping, forming a diode. A first layer 2 has n-type doping whereas the second layer 3 has p-type doping. A conducting zone 5, which may be a silicon layer, a doped silicon layer or a metal layer, lies beneath the second layer 3.

The photodiode 1 thus described is generally intended to be integrated into a matrix sensor. It is therefore necessary to isolate a given photodiode from the neighboring photodiodes. To do this, deep isolation trenches 4 are formed so as to separate two immediately adjacent photodiodes. The deep isolation trenches (DTIs) 4 are made of an insulating material.

Moreover, the external face of the photodiode is protected from the outside by a passivation layer 6, also made of an insulating material.

A space charge zone, in which the incident electromagnetic radiation may be absorbed, is created at the interface between the first layer 2 and the second layer 3. The absorption then gives rise to the creation of electron-hole pairs. The electrons and holes each migrate in opposite directions under the effect of the electric field in the space charge zone. The displacement of the photogenerated electrons and holes thus gives rise to the creation of a photoelectric current.

As described above, the deep isolation trenches 4 are generally made of an insulator of the oxide or nitride type and have the property of generating a positive charge at the interface with a semiconductor. In the case of the photodiode described in FIG. 1, such as a positive charge layer may generate a field sufficient to attract and capture the photogenerated electrons, thus correspondingly reducing the photoelectric current.

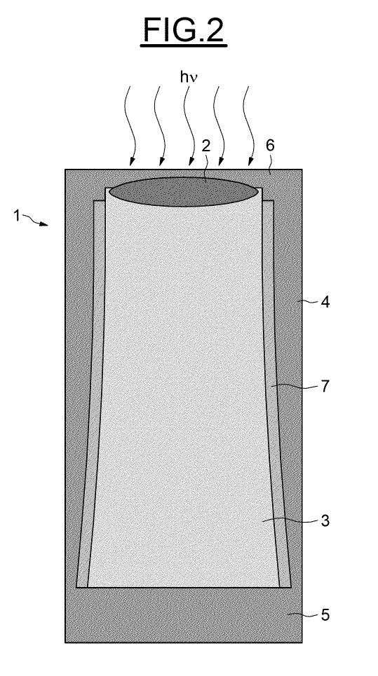

It is proposed to produce a protective layer 7 illustrated in FIG. 2. This protective layer 7 makes it possible to create a layer of negative charge at the interface with the first layer 2 and the second layer 3 so as to repel the photogenerated electrons so as to reduce the risks of capture.

The protective layer 7 is created by the ion implantation of p-type doping species at the interface between, on one side, the doped silicon of the first layer 2 and of the second layer 3 and, on the other side, the dielectric of the deep isolation trench. The implanted ions must remain localized at the interface so as not to disturb the operation of the active zones. To do this, carbon is also implanted, which has the property of minimizing the diffusion of boron and indium (or other element) into the silicon. Thus, during the thermal annealing steps, the implanted species remain localized at the interface between the silicon and the deep isolation trenches.

The implanted species are p-type dopants and may in particular be boron or indium or other element.

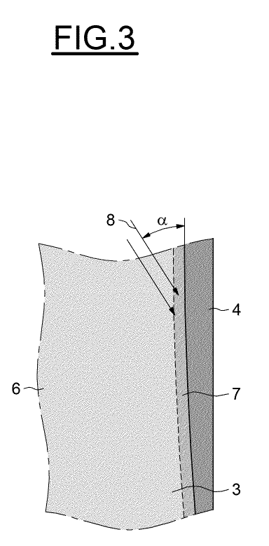

FIG. 3 illustrates the implantation of the species so as to form the protective layer 7.

The implantation takes place at an angle α to the normal to the surface of the silicon layers. The angle α may be between 2° and 26°.

The dose is between 10¹¹ and 10¹³ at.cm^{˜}2.

The implantation energy is between less than 1 keV and 25 keV.

The features of a photodiode that includes deep isolation trenches are improved by implanting a protective layer so that a negative charge zone appears at the interface between the silicon and the deep isolation trench. By preventing the recombination of photogenerated electrons, the protective layer makes it possible to improve the contrast, the dark current and the intensity of the photogenerated current.

What is claimed is:

1. A photodiode, comprising:
a first doped layer; and
a second doped layer having a common face with the first doped layer;
at least one deep isolation trench having a face contiguous with the first doped layer and the second doped layer;
a conducting layer in contact with a free face of the second doped layer; and
a protective layer configured to generate a layer of negative charge at an interface between, on one side, the first doped layer and the second doped layer and, on the other side, the deep isolation trench.

2. The photodiode according to claim 1, wherein the protective layer includes implanted p-type doping species.

3. The photodiode according to claim 1, wherein the protective layer includes implanted doping species selected from the group consisting of boron and indium.

4. The photodiode according to claim 1, wherein the protective layer includes implanted doping species and implanted carbon.

5. A process for producing at least one deep isolation trench adjacent a photodiode comprising a first doped layer and a second doped layer having a common face with the first doped layer, wherein a free face of the second doped layer is in contact with a conducting layer, comprising:
forming a protective layer by implanting a doping species at an interface between, on one side, a first doped layer and a second doped layer and, on the other side, the deep isolation trench,
the implanted doping species having the property of creating a layer of negative charge in contact with the first and second doped laters.

6. The process according to claim 5, wherein the implanted species is a p-type doping species.

7. The process according to claim 6, wherein the p-type doping species is selected from the group consisting of boron and indium.

8. The process according to claim 5, wherein forming the protective layer further comprises implanting carbon at the interface.

9. The process according to claim 5, wherein forming the protective layer further comprises co-implanting at least two different species.

10. The process according to claim 5 wherein forming the protective layer further comprises implanting the doping species at the interface at an implantation angle of between 2° and 26°.

11. A photodiode, comprising:
a first layer of a first doping type;
a second layer of a second doping type immediately beneath the first layer;
an isolation trench; and
a protective layer located at an interface between the isolation trench and the first and second layers, the protective layer including doping species configured to provide a layer of negative charge at the interface.

12. The photodiode of claim 11 wherein the protective layer is doped with a p-type doping species.

13. The photodiode of claim 11 wherein the p-type doping species is selected from the group consisting of boron and indium.

13. The photodiode of claim 11 wherein the protective layer includes implanted doping species and implanted carbon.

14. A method, comprising:
forming a first doped layer;
forming a second doped layer on top of the first doped layer;
forming an isolation trench;
implanting a doping species at an interface between, on one side, the first and second doped layers and, on the other side, the isolation trench.

15. The method of claim 14 wherein the doping species is a p-type doping species configured to provide a layer of negative charge at the interface.

16. The method of claim 14 wherein implanting the doping species further comprises implanting carbon at the interface.

17. The method of claim 14 wherein implanting further comprises implanting at an implantation angle of between 2° and 26°.
